(19) United States
(12) Patent Application Publication
(10) Pub. No.: US 2005/0263681 A1
(43) Pub. Date: Dec. 1, 2005

(54) Active pixel having buried transistor

(75) Inventor: Xinping He, San Jose, CA (US)

Correspondence Address: PERKINS COIE LLP;PATENT-SEA, P.O. BOX 1247, SEATTLE, WA, 98111-1247, US

(73) Assignee: OmniVision Technologies, Inc., Sunnyvale, CA (US)

(21) Appl. No.: 11/201,666

(22) Filed: Aug. 11, 2005

Related U.S. Application Data
(63) Continuation-in-part of application No. 10/816,071, filed on Mar. 30, 2004.

(51) Int. Cl. H01J 40/14; H01L 31/062

(52) U.S. Cl. 250/214 R

(57) ABSTRACT

An active pixel for an image sensor that has minimized 1/f noise. The active pixel includes an amplification transistor that is implemented as a “body current” transistor. This minimizes the effect of surface oxide traps that are believed to cause 1/f noise. Further, the reset transistor, the row select transistor, and transfer transistor of the active pixel may also be implemented as a body current transistor to further reduce 1/f noise.

### CROSS-REFERENCE TO RELATED APPLICATION

This application is a Continuation-In-Part of U.S. patent application Ser. No. 10/816,071, entitled “Active Pixel Having Buried Transistor,” filed Mar. 30, 2004.

### TECHNICAL FIELD

The embodiments of the present invention relate, in general, to image sensors and, in particular, to CMOS image sensors that use buried transistors to minimize 1/f noise.

### BACKGROUND

CMOS image sensors have become ubiquitous. They are widely used in digital still cameras, security cameras, cellular phones, medical, and automobile applications. The technology used to manufacture CMOS image sensors has continued to advance at great pace. For example, the demands of higher resolution and lower power consumption have encouraged the further miniaturization and integration of the image sensor. As the pixels in the image sensors become smaller and smaller, the associated active elements within the pixels, such as the various transistors, also become smaller.

One result of this increased integration is the effect of 1/f noise. As the transistors in each of the pixels become smaller, 1/f noise becomes more of a concern. It is believed that the 1/f noise (also referred to as “flicker noise”) is caused by switching transistors through the introduction of oxide traps at the surface, which act to trap and de-trap electrons. As applied to the transistors used in an active pixel of a CMOS image sensor, the switching on and off of the various transistors will cause 1/f noise within the pixel.

### BRIEF DESCRIPTION OF THE DRAWINGS

FIG. 1 is a schematic diagram of a prior art three transistor active pixel used in a CMOS image sensor.

FIG. 2 is a schematic diagram of a prior art four transistor active pixel used in a CMOS image sensor.

FIG. 3 is a schematic diagram of a three transistor active pixel formed in accordance with the present invention.

FIG. 4 is a schematic diagram of a four transistor active pixel formed in accordance with the present invention.

### DETAILED DESCRIPTION

In the following description, numerous specific details are provided to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

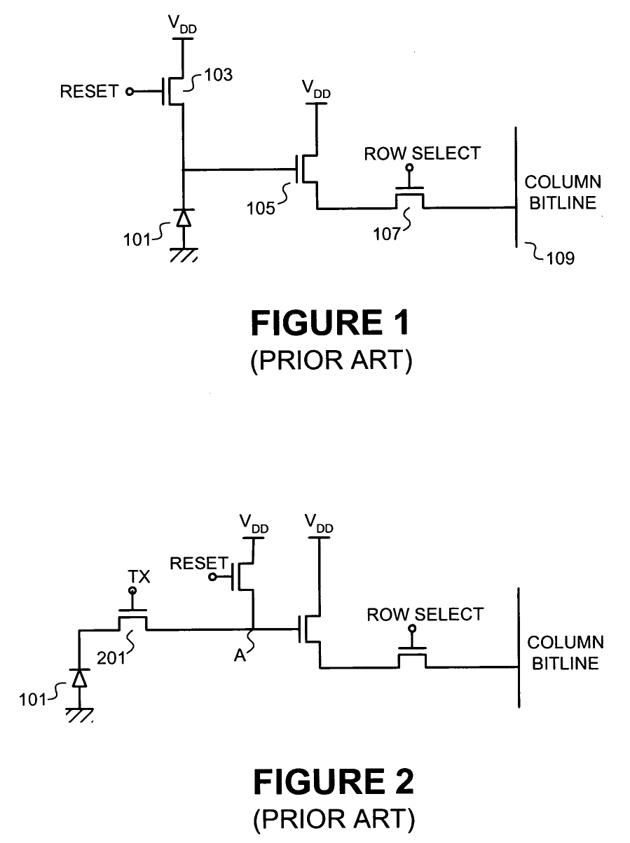

FIG. 1 illustrates a prior art CMOS active pixel that uses three transistors. A light sensing element 101 outputs a signal that is used to modulate an amplification transistor 105. The amplification transistor is also known as a source-follower transistor. The light sensing element 101 can be one of a variety of devices, including without limitation, photogates, photodiodes, pinned photodiodes, partially pinned photodiodes, etc.

During an integration period, the light sensing element 101 captures light and outputs a signal indicative of the amount of light incident onto that light sensing element 101. The signal is used to modulate the amplification transistor 105. After the integration period, a reset transistor 103 is used to reset the level of the light sensing element output node to a reference level. Finally, a row select transistor 107 is used as a means to address the pixel and to selectively read out the signal from the pixel onto a column bit line 109.

FIG. 2 is similar in many respects to the three transistor active pixel of FIG. 1, except that an additional transfer transistor 201 is used to transfer the signal output by the light sensing element 101 to a floating node A. Although a four transistor active pixel may be larger in size because of the transfer gate 201, advantages relative to the three transistor active pixel of FIG. 1 are still gained.

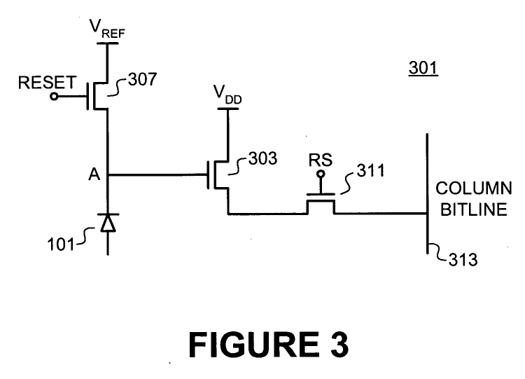

Turning to FIG. 3, a three transistor active pixel 301, formed in accordance with the present invention, is shown. In this active pixel, a light sensing element 101 (which includes without limitation photogates, photodiodes, pinned photodiodes (sub-species of photodiodes), partially pinned photodiodes (sub-species of photodiodes and the like) has its output connected directly to an amplification transistor 303. The gate of the amplification transistor 303 is also referred to as sense node A.

As seen in FIG. 3, the overall structure of the active pixel of an embodiment of the present invention is similar to that of the prior art shown in FIG. 1. However, one important distinction between the embodiments of the invention and the prior art is that one or more of the transistors located in the active pixel are formed to have some, most, or all of the source to drain current flow not at the surface (as is the case with conventional enhancement mode transistors), but rather flow through the body of the transistor below the surface. By having the current flow through the body of the transistor, the surface oxide traps are avoided.

There are several possible transistor devices that may be suitable. For example, a depletion mode transistor may be used. Alternatively, a buried transistor may be used. Still alternatively, various types of back biasing may be used to encourage current to flow through the body of the transistor and not the surface. Any current or future devices that routes current through the body of the transistor and not the surface is within the scope of this invention and may be utilized. This is referred to herein as a “body current” device.

A buried-channel transistor (a body current device) may be implemented by additional layers of semiconductor placed under the surface. It enhances charge movement by reducing possible trap sites and decreasing the transfer time. The total charge storage capacity is reduced by many folds and the overall dynamic range and sensitivity drastically increases.

In the literature of this field, the term “buried-channel” is used in contrast with “surface-channel.” In a surface-channel the charge movement occurs on the “surface” of the device. Some of the major drawbacks of a surface-channel device are the presence of trapping states that occur at boundaries of gates; loss of transfer efficiency; and undesirability for faint light applications.

Buried-channels are functionally similar to their surface-channel counterparts, while they have some differences based on some specific device concepts. Their main difference is in the location of the charge packet. In a surface-channel device, the charge is located at the surface, while in a buried-channel device it is located within the semiconductor and away from the surface. In general, 1/f noise is caused at the surface of a device. Some of the embodiments of this invention utilize the NMOS transistors for this purpose. In other embodiments additional process steps are used to shield the surface.

As noted above, one alternative is the use of buried transistors. Thus, either the amplification transistor, the reset transistor 307, or the row select transistor 311, or all of them, may be implemented as a buried transistor. Typically, the greatest advantage is obtained when the amplification transistor is substituted with a “body current” device, such as a buried transistor or depletion mode transistor.

There are various methods of implementing a buried transistor, such as the use of silicon on insulator technology, and any of the methods would be suitable. For example the techniques disclosed in U.S. Pat. No. 6,900,500, entitled “Buried transistors for silicon on insulator technology,” issued to Taylor et al, and the U.S. Pat. No. 6,759,282, entitled “Method and structure for buried circuits and devices,” issued to Campbell et al, provide examples of how buried transistors may be formed. While these pending applications are simply two examples of how buried transistors may be formed, any of the myriad of methods for forming a buried transistor may be used and implemented in the embodiments of the invention.

It has been discovered by the inventor that the use of a buried transistor, such as for the amplification transistor 303, significantly reduces 1/f noise. Therefore, the use of buried transistors in the active pixels provides an advantage over the prior art. Note that the operation of the active pixel is substantially similar to a normal three or four transistor pixel.

Specifically, once the signal from the light sensing element 101 has been placed onto the sense node A, operation of the active pixel is similar to that of FIGS. 1 and 2. In other words, the signal on the sense node A is periodically reset using the reset transistor 307. Further, the signal on the sense node is used to modulate the amplification transistor 303 to output an amplified signal onto the column bitline 313. The row select transistor 311 is used to selectively address the pixel.

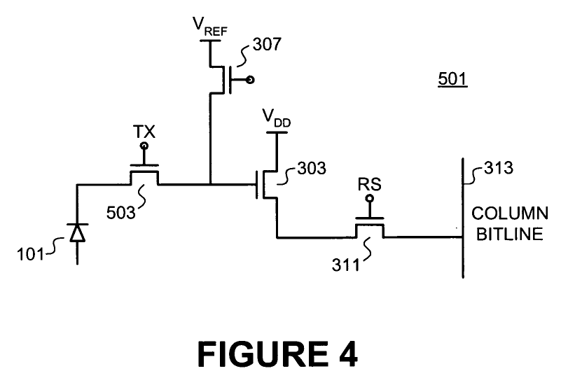

Turning now to FIG. 4, a schematic view of a four transistor active pixel is shown. Similar to the description with respect to FIG. 3, a buried transistor is utilized for the amplification transistor 303 and may optionally be utilized for the reset transistor 307 or row select transistor 311. Furthermore, the transfer transistor 503 may also be implemented as a buried transistor.

It can be appreciated that what is shown in FIGS. 3-4 is but one pixel in an array of pixels that form an image sensor. In many embodiments, the number of pixels in the image sensor array can range from hundreds of pixels to millions of pixels. Typically, the image sensor array has many pixels arranged as rows and columns. However, the teachings of the invention can be utilized in a variety of architectures.

The description of the embodiments of the invention and their applications as set forth herein is illustrative and is not intended to limit the scope of the invention. Variations and modifications of the embodiments are possible and practical alternatives to, or equivalents of the various elements of, the embodiments disclosed herein and are known to those of ordinary skill in the art. Further, the various doping types may be reversed, such that an n-channel transistor described above may be replaced with a p-channel transistor. These and other variations and modifications of the disclosed embodiments may be made without departing from the scope and spirit of the invention.

### CONCLUSION

Unless the context clearly requires otherwise, throughout the description and the claims, the words “comprise,” “comprising,” and the like are to be construed in an inclusive sense, as opposed to an exclusive or exhaustive sense;
that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof.

Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize.

The teachings of the invention provided herein can be applied to other systems, not necessarily the system described above. The elements and acts of the various embodiments described above can be combined to provide further embodiments.

Changes can be made to the invention in light of the above Detailed Description. While the above description describes certain embodiments of the invention, and describes the best mode contemplated, no matter how detailed the above appears in text, the invention can be practiced in many ways. Details of the compensation system described above may vary considerably in its implementation details, while still being encompassed by the invention disclosed herein.

As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

While certain aspects of the invention are presented below in certain claim forms, the inventors contemplate the various aspects of the invention in any number of claim forms. Accordingly, the inventors reserve the right to add additional claims after filing the application to pursue such additional claim forms for other aspects of the invention

1. In an image sensor, an active pixel comprising:
a light sensing element formed in a semiconductor substrate;
a sense node in electrical communication with the light sensing element for outputting a signal produced by the light sensing element; and
an amplification transistor controlled by the sense node, wherein the amplification transistor is a buried NMOS transistor formed in the semiconductor substrate.

2. The pixel of claim 1, wherein the light sensing element is selected from the group consisting of photodiode, pinned photodiode, partially pinned photodiode, and photogate.

3. The pixel of claim 1 further including a transfer transistor operative to transfer the signal from the light sensing element to the sense node.

4. The pixel of claim 1 wherein the amplification transistor outputs an amplified version of the signal to a column bitline.

5. The pixel of claim 1 further including a reset transistor operative to reset the sense node to a reference voltage.

6. The pixel of claim 1 wherein the buried transistor is replaced with a depletion mode transistor.

7. An active pixel for use in a CMOS image sensor, the pixel comprising:
a light sensing element formed in a semiconductor substrate;
a sense node;
a transfer transistor operative to transfer a signal produced by the light sensing element to the sense node;
an amplification transistor controlled by the sense node; and
wherein the amplification transistor, the transfer transistor, or both, are body current NMOS transistors formed in the semiconductor substrate.

8. The pixel of claim 7 wherein the light sensing element is selected from the group consisting of photodiode, pinned photodiode, partially pinned photodiode, and photogate.

9. The pixel of claim 7 wherein the transfer transistor is implemented as a buried transistor.

10. The pixel of claim 7 wherein the amplification transistor outputs an amplified version of the signal to a column bitline.

11. The pixel of claim 7 further including a reset transistor operative to reset the sense node to a reference voltage.

12. The pixel of claim 7 wherein the body current transistor is a buried transistor or a depletion mode transistor formed in said semiconductor substrate.

13. A two dimensional image sensor array on a semiconductor substrate, comprising:
multiple active pixels, wherein each pixel further includes:
a light sensing element;
a sense node in electrical communication with the light sensing element;
a transfer transistor in electrical communication with the light sensing element and the sense node; and
an amplification transistor controlled by the sense node, wherein at least one transistor of a pixel is a buried transistor.

14. The image sensor of claim 13, wherein the light sensing element is selected from the group consisting of photodiode, pinned photodiode, partially pinned photodiode, and photogate.

15. The image sensor of claim 13, wherein the amplification transistor outputs an amplified version of the signal to a column bitline.

16. The image sensor of claim 13, further including a reset transistor operative to reset the sense node to a reference voltage.

17. The image sensor of claim 13, wherein the buried transistor is replaced with a depletion mode transistor.

18. The image sensor of claim 13, wherein a reset transistor or a row select transistor is implemented as a buried transistor.

19. The image sensor of claim 13, wherein buried transistors are NMOS.
